(19) United States
(12) Patent Application Publication
(10) Pub. No.: US 2024/0421262 A1
(43) Pub. Date: Dec. 19, 2024

(54) LIGHT-EMITTING DEVICE

(71) Applicant: EPISTAR CORPORATION, Hsinchu (TW)

(72) Inventors: Yen-Liang KUO, Hsinchu (TW); Chao-Hsing CHEN, Hsinchu (TW); Chi-Shiang HSU, Hsinchu (TW); Chung-Hao WANG, Hsinchu (TW)

(21) Appl. No.: 18/743,847

(22) Filed: Jun. 14, 2024

(30) Foreign Application Priority Data
Jun. 15, 2023 (TW) 112122326

(51) Int. Cl. H01L 33/46

(52) U.S. Cl. CPC H01L 33/46

(57) ABSTRACT

A light-emitting device comprises a first semiconductor layer; a semiconductor mesa, comprising an active layer and a second semiconductor layer and comprising an inclined surface connected to the first semiconductor layer; a contact electrode covering the second semiconductor layer and comprising an upper surface; a reflective structure comprising a reflective structure opening having a first side surface and a second side surface; a connection layer covering the reflective structure; and a metal reflective layer covering the connection layer; wherein in a cross-sectional view of the light-emitting device, a first portion of a projection of the first side surface to the upper surface of the contact electrode comprises a first length, a second portion of a projection of the second side surface to the upper surface of the contact electrode comprises a second length, and the first length is smaller than the second length.

### TECHNICAL FIELD

The application relates to a light-emitting device, more specifically, to a flip-chip light-emitting device comprising a metal reflective layer and a reflective structure.

### REFERENCE TO RELATED APPLICATION

This application claims the right of priority based on Taiwan Application Serial No. 112122326, filed on Jun. 15, 2023, and the content of which is hereby incorporated by reference in its entirety.

### DESCRIPTION OF BACKGROUND ART

Light-emitting diode (LED) is a solid-state semiconductor light-emitting device, which has the advantages of low power consumption, low heat generation, long lifetime, shockproof, small size, high response speed and good optical-electrical characteristics, such as stable emission wavelength. Therefore, light-emitting diodes have been widely applied in household appliances, equipment indicator lights, and optoelectronic products, and so forth.

### SUMMARY OF THE APPLICATION

In accordance with an embodiment of the present application, a light-emitting device comprises a first semiconductor layer; a semiconductor mesa, comprising an active layer and a second semiconductor layer and comprising an inclined surface connected to the first semiconductor layer; a contact electrode covering the second semiconductor layer and comprising an upper surface; a reflective structure comprising an insulating reflective mirror and an insulating layer located between the contact electrode and the insulating reflective mirror, wherein the reflective structure comprises a reflective structure opening and the reflective structure opening comprises a first side surface and a second side surface; a connection layer covering the reflective structure and filling into the reflective structure opening; and a metal reflective layer covering the connection layer and filling into the reflective structure opening; wherein in a cross-sectional view of the light-emitting device, a first portion of a projection of the first side surface to the upper surface of the contact electrode comprises a first length, a second portion of a projection of the second side surface to the upper surface of the contact electrode comprises a second length, and the first length is smaller than the second length.

### BRIEF DESCRIPTION OF THE DRAWINGS

The above and other aspects of the application will become better understood with regard to the following detailed description of the preferred but non-limiting embodiment(s). The following description is made with reference to the accompanying drawings. It is noted that, in accordance with the standard practice in the industry, various features are not drawn to scale. In fact, the dimensions of the various features may be arbitrarily increased or reduced for clarity of discussion.

FIG. 1 shows a top view of a light-emitting device 1 according to an embodiment of the present application.

FIG. 2 shows a cross-sectional view of the light-emitting device 1 along line L-L′ in FIG. 1.

FIG. 3 shows a partial enlarged view of region A defined by the dash line of FIG. 1.

FIG. 4 shows a cross-sectional view along line X-X′ in FIG. 3.

FIGS. 5A-5D show cross-sectional views of manufacturing the reflective structure opening of the light-emitting device 1 according to an embodiment of the present application.

FIGS. 6A-6B show cross-sectional views of manufacturing the first reflective structure opening of the light-emitting device 1 according to an embodiment of the present application.

FIG. 7A shows a side view of a reflective structure opening according to an embodiment of the present application.

FIG. 7B shows a partial enlarged view of the first reflective structure opening of region B defined by the dash line of FIG. 7A.

FIG. 8 shows a partial enlarged view of the first reflective structure opening of region B defined by the dash line of FIG. 7A according to another embodiment of the present application.

FIGS. 9A-9C show partial top views of a light-emitting device 1 according to an embodiment of the present application.

FIG. 10 shows a schematic view of a light-emitting apparatus 2 according to an embodiment of the present application.

FIG. 11 shows a schematic view of a light-emitting apparatus 3 according to an embodiment of the present application.

FIG. 12 shows a schematic view of a backlight module 4 according to an embodiment of the present application.

FIG. 13 shows a schematic view of a display 5 according to an embodiment of the present application.

FIG. 14 shows a schematic view of a light-emitting apparatus 6 according to an embodiment of the present application.

FIG. 15 shows a schematic view of a light-emitting apparatus 7 according to an embodiment of the present application.

### DETAILED DESCRIPTION OF THE APPLICATION

The following disclosure provides many different embodiments for implementing different features of the present application. The following disclosure describes specific examples of each element and its arrangement to simplify the explanation. These specific examples are not intended to be limited. For example, if the embodiment of the present disclosure describes that a first feature is formed on or above a second feature, it means that the first feature and the second feature are in direct contact, or additional features are formed between the first feature and the second feature such that the first feature and the second feature may not be in direct contact.

It should be understood that other operating steps may be performed before, between or after the method, and in other embodiments of the method, part of the operating steps may be replaced or omitted.

In addition, space-related words may be used, such as “under”, “below”, “lower”, “above”, “on”, “higher” and the related, these spatially related terms are used to facilitate the description of the relationship between one element or feature(s) and another element or feature(s) in the illustrations. These spatially related terms include the various orientations of the device in use or operation, and the orientation depicted in the drawings. When the device is rotated to different orientations (rotated 45 degrees or at any other orientation), the spatially relative adjectives used in the device will be interpreted in accordance with the rotated orientation. Furthermore, when it is in said that a first material layer is located on or above a second material layer, it includes the situation where the first material layer and the second material layer are in direct contact, or there may be one or more other materials disposed between them. In the case, there may not be direct contact between the first material layer and the second material layer. In some embodiments of the present disclosure, unless otherwise defined, terms related to joining and connecting, such as “connection” or “interconnection”, may mean that two structures are in direct contact, or may also mean that two structures are not in direct contact and there are other structures located between these two structures. And the terms about joining and connecting can also include the situation where both structures are movable or both structures are fixed.

In the specification, the terms “about”, “nearly”, “roughly”, “approximately”, “substantially”, “same”, and “similar” usually indicate within +15% of a characteristic value of a given value, or within +10%, or within +5%, or within +3%, or within +2%, or within +1%, or within the range of +0.5%. The quantities given here are approximate quantities, that is, in the absence of specific instructions for “about”, “nearly”, “roughly”, “approximately”, and “substantially”, they may still imply the meaning of “about”, “nearly”, “roughly”, “approximately”, and “substantially”.

It should be understood that, although the terms “first”, “second”, “third”, etc. are used herein to describe various elements, parts, regions, layers and/or sections, and these elements, parts, regions, layers and/or sections should not be limited by these terms. These terms may only be used to distinguish one element, part, region, layer or section from another element, part, region, layer or section. Thus, a first element, part, region, layer or section discussed below could be termed as a second element, part, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure. It should not be interpreted in an idealized or overly formal manner unless specifically defined in the embodiments of this present disclosure.

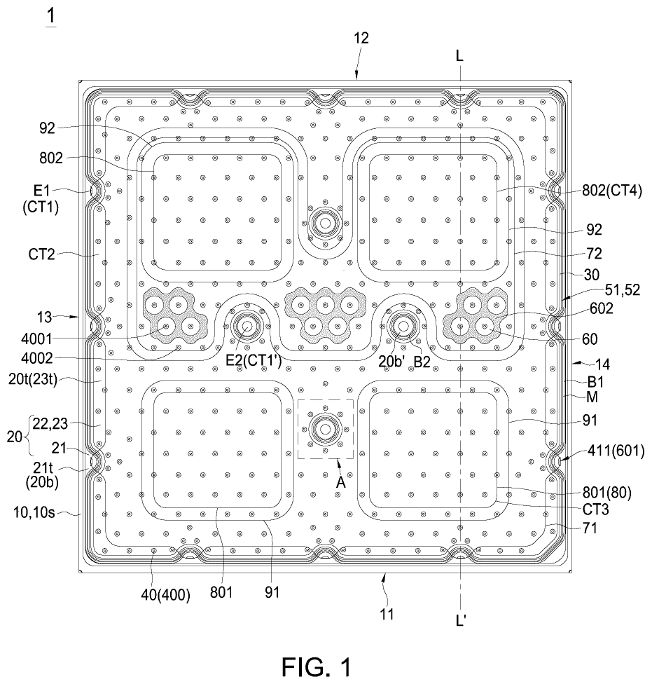

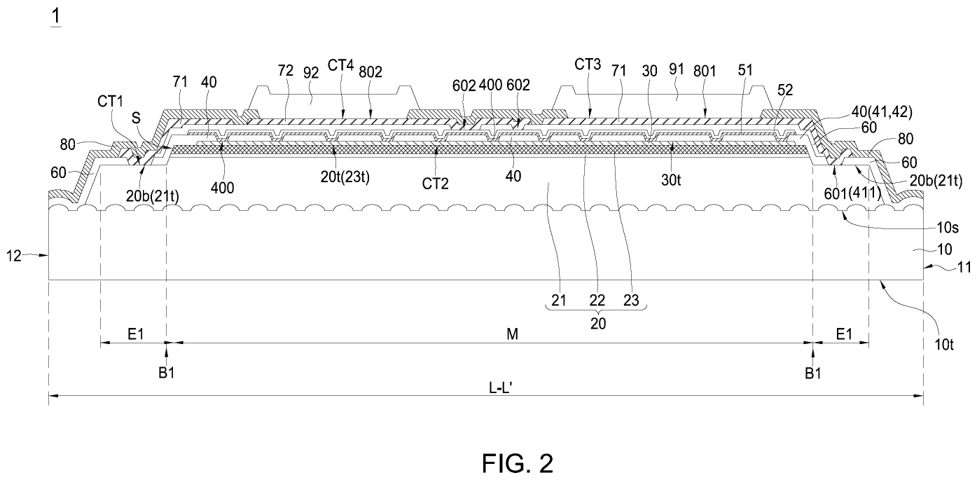

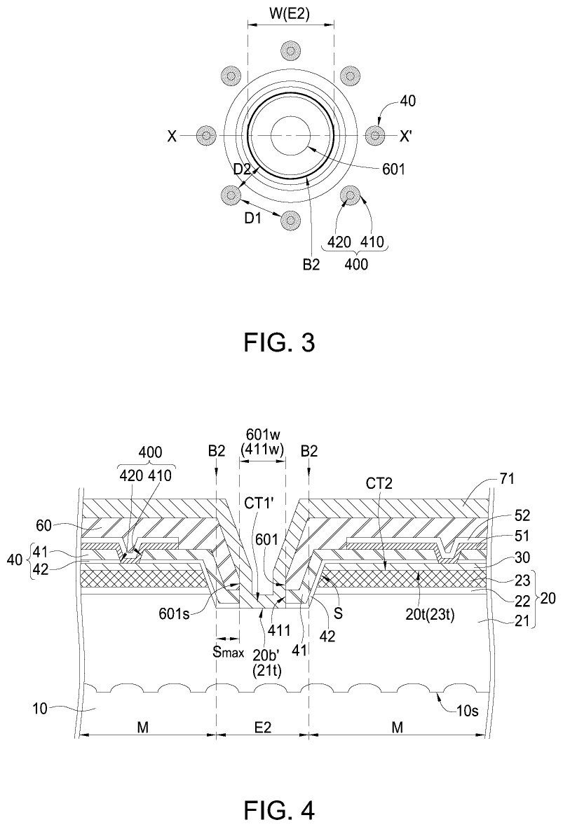

FIG. 1 shows a top view of a light-emitting device 1 according to an embodiment of the present application. FIG. 2 shows a cross-sectional view along line L-L′ in FIG. 1. FIG. 3 shows a top view of region A of the reflective structure opening 400 defined by the dash line of FIG. 1. FIG. 4 shows a cross-sectional view along line X-X′ in FIG. 3.

As shown in FIGS. 1, 2, 3 and 4, a light-emitting device 1 according to an embodiment comprises a substrate 10 having an upper surface 10s, a first semiconductor layer 21 located on the upper surface 10s of the substrate 10, and a semiconductor mesa M located on the first semiconductor layer 21. The semiconductor mesa M comprises an active layer 22 and a second semiconductor layer 23, and comprises an inclined surface S connected to the first semiconductor layer 21. A contact electrode 30 is located on the second semiconductor layer 23 and covers the second semiconductor layer 23. A reflective structure 40 is located on the contact electrode 30 and comprises one or a plurality of reflective structure openings 400 to expose the contact electrode 30, and one or a plurality of contact structure openings 411 to expose the first semiconductor layer 21. A connection layer 51 covers the reflective structure 40 and fills into one or a plurality of reflective structure openings 400. A metal reflective layer 52 is located on the connection layer 51 and fills into one or a plurality of reflective structure openings 400. A second insulating layer 60 covers the connection layer 51, the metal reflective layer 52 and the reflective structure 40, and comprises a first opening 601 of the second insulating layer 60 located on the first semiconductor layer 21 and a second opening 602 of the second insulating layer 60 on the metal reflective layer 52. A first extension electrode 71 covers the semiconductor mesa M and covers the first opening 601 of the second insulating layer 60. A second extension electrode 72 covers the semiconductor mesa M and covers the second opening 602 of the second insulating layer 60. A protection layer 80 covers the first extension electrode 71 and the second extension electrode 72 and comprises a first opening 801 of the protection layer 80 located on the first extension electrode 71 and a second opening 802 of the protection layer 80 on the second extension electrode 72. A first electrode pad 91 covers the first opening 801 of the protection layer 80 and is electrically connected to the first semiconductor layer 21 through the first extension electrode 71. A second electrode pad 92 covers the second opening 802 of the protection layer 80 and is electrically connected to the second semiconductor layer 23 through the second extension electrode 72.

The substrate 10 can be a growth substrate for the epitaxial growth of a semiconductor structure 20. In one embodiment, the semiconductor structure 20 comprises a first semiconductor layer 21, an active layer 22, and a second semiconductor layer 23. The substrate 10 comprises gallium arsenide (GaAs) wafer for epitaxially growing aluminum gallium indium phosphide (AlGaInP), or sapphire (Al₂O₃) wafer, gallium nitride (GaN) wafer, silicon carbide (SiC) wafer, or aluminum nitride (AlN) wafer for epitaxially growing gallium nitride (GaN), indium gallium nitride (InGaN), or aluminum gallium nitride (AlGaN).

In one embodiment of the present application, the light-emitting device 1 may not comprise a substrate 10. For example, the substrate 10 may be a growth substrate for growing the semiconductor structure 20. Then, the substrate 10 can be separated from the semiconductor structure 20 by laser lift off or chemical lift-off.

In one embodiment of the present application, the semiconductor structure 20 with optoelectronic characteristics, such as light-emitting stack, can be formed on the substrate 10 by metal-organic chemical vapor deposition (MOCVD), molecular beam epitaxy (MBE), hydride vapor phase epitaxy (HVPE), physical vapor deposition (PVD), or ion plating. Physical vapor deposition comprises sputtering or evaporation.

The wavelength of the light emitted from the light-emitting device 1 is adjusted by changing the physical and chemical composition of one or more layers in the semiconductor structure 20. The semiconductor structure 20 comprises a first semiconductor layer 21, an active layer 22, and a second semiconductor layer 23. The material of the semiconductor structure 20 comprises a group III-V semiconductor material, such as AlₓIn_{y}Ga_{(1-x-y)}N or AlₓIn_{y}Ga_{(1-x-y)}P, wherein 0≤x, y≤1; (x+y)≤1. According to the material of the active layer 22, when the material of the semiconductor structure 20 is AlInGaP material, red light having a wavelength between 610 nm and 650 nm or yellow light having a wavelength between 550 nm and 570 nm can be emitted. When the material of the semiconductor structure 20 comprises InGaN material, blue light having a wavelength between 400 nm and 490 nm or green light having a wavelength between 530 nm and 570 nm can be emitted. When the material of the semiconductor structure 20 comprises AlGaN or AlInGaN material, UV light having a wavelength between 250 nm and 400 nm can be emitted.

The first semiconductor layer 21 and the second semiconductor layer 23, such as a cladding layer or a confinement layer, have different conductivity types, electrical properties, polarities, or doping elements for providing electrons or holes. For example, the first semiconductor layer 21 is an n-type semiconductor, and the second semiconductor layer 23 is a p-type semiconductor. The active layer 22 is formed between the first semiconductor layer 21 and the second semiconductor layer 23. The electrons and holes combine in the active layer 22 under a current driving to convert electric energy into light energy to emit a light. The active layer 22 can be a single heterostructure (SH), a double heterostructure (DH), a double-side double heterostructure (DDH), or a multi-quantum well structure (MQW). The material of the active layer 22 can be i-type, p-type, or n-type semiconductor. The first semiconductor layer 21, the active layer 22, or the second semiconductor layer 23 may be a single layer or a structure comprising a plurality of sub-layers.

In one embodiment, the semiconductor structure 20 can further comprise a buffer layer (not shown) located between the first semiconductor layer 21 and the substrate 10 to release the stress caused by lattice mismatch between the materials, the lattice dislocation and the lattice defect can thus be reduced and the epitaxial quality can be improved. The buffer layer can be a single layer or a structure comprising a plurality of sub-layers. In one embodiment, an aluminum nitride (AlN) layer formed by PVD method can be the buffer layer located between the semiconductor structure 20 and the substrate 10 to improve the epitaxial quality of the semiconductor structure 20. In one embodiment, the target is composed of aluminum nitride when the aluminum nitride (AlN) layer is formed by PVD method. In another embodiment, a target composed of aluminum can be used, and aluminum nitride can be formed by reacting the aluminum target with a nitrogen source.

As shown in FIGS. 2 and 4, the semiconductor structure 20 comprises a first recessed region E1, a second recessed region E2, and a semiconductor mesa M surrounded by the first recessed region E1. In one embodiment, the first recessed region E1 and the second recessed region E2 can be formed by etching to remove the second semiconductor layer 23, the active layer 22 and a portion of the first semiconductor layer 21. In other words, the first recessed region E1 and the second recessed region E2 expose an upper surface 21t of the first semiconductor layer 21. In a top view of the light-emitting device 1, as shown in FIG. 1, the first recessed region E1 is located on one side of the semiconductor mesa M, and the second recessed region E2 is located inside the semiconductor mesa M and is surrounded by the semiconductor mesa M. In FIG. 2, the symbol “B1” represents a first boundary B1 between the first recessed region E1 and the semiconductor mesa M. In FIG. 4, mark “B2” represents a second boundary B2 between the second recessed region E2 and the semiconductor mesa M. An upper surface 20t of the semiconductor mesa M (an upper surface 23t of the second semiconductor layer 23) may be higher than an upper surface 20b of the first recessed region E1 (an upper surface 21t of the first semiconductor layer 21) and an upper surface 20b′ of the second recessed region E2 (an upper surface 21t′ of the first semiconductor layer 21). In one embodiment, the semiconductor mesa M may become narrower toward its top. Therefore, the side surface of the semiconductor mesa M can be an inclined surface S.

As shown in FIGS. 2 and 4, in one embodiment, a part of the upper surface 20b of the first recessed region E1 can be a first contact region CT1, and a part of the upper surface 20b′ of the second recessed region E2 can be a first contact subregion CT1′. In one embodiment, a part of the upper surface 20t of the semiconductor mesa M is defined as a second contact region CT2. The reflective structure 40 comprises a plurality of contact structure openings 411 to expose the first contact region CT1 and the first contact subregion CT1′, and comprises a plurality of reflective structure openings 400 located on the second contact region CT2 to expose the contact electrode 30. In one embodiment, a ratio (A1/A2) of a first total area A1 of the plurality of first contact subregions CT1′ to a second total area A2 of the plurality of first contact regions CT1 is in a range between 1 and 2 to improve the current distribution of the light-emitting device 1. When the ratio (A1/A2) is less than 1, the brightness of the light-emitting device 1 is decreased. When the ratio (A1/A2) is greater than 2, the voltage (Vf) of the light-emitting device 1 is increased.

As shown in FIG. 1, the substrate 10 comprises a first side 11, a second side 12, a third side 13 and a fourth side 14. The semiconductor mesa M can be spaced apart from those sides of the first side 11 to the fourth side 14, and the first recessed region E1 can be disposed between the semiconductor mesa M and any one side or any sides of the first side 11 to the fourth side 14. For example, the first recessed region E1 can be disposed between the semiconductor mesa M and the first side 11 and between the semiconductor mesa M and the second side 12, or between the semiconductor mesa M and the third side 13 and between the semiconductor mesa M and the fourth side 14. The first side 11 and the second side 12 can be opposite to each other, and the third side 13 and the fourth side 14 can be opposite to each other. In one embodiment, a plurality of second recessed regions E2 spaced apart from each other having a long stripped, rectangular, circular or elliptical shape can be disposed inside the semiconductor mesa M.

As shown in FIG. 2, the contact electrode 30 comprises an upper surface 30t and can be directly disposed on the second semiconductor layer 23. The region where the contact electrode 30 contacts the second semiconductor layer 23 constitutes the second contact region CT2, and the contact electrode 30 is electrically connected to the second semiconductor layer 23. The contact electrode 30 can spread the current injected from the outside and then inject it into the second semiconductor layer 23 via the upper surface 20t of the semiconductor mesa M (the upper surface 23t of the second semiconductor layer 23).

As shown in FIGS. 1 and 3, in a top view of the light-emitting device 1, the reflective structure opening 400 comprises a circle, a semicircle, an ellipse, a triangle, a rectangle, a polygon, an arc, or an annular shape. In one embodiment, the reflective structure 40 comprises a plurality of reflective structure openings 400 disposed on the semiconductor mesa M. The plurality of reflective structure openings 400 may be arranged on the semiconductor mesa M in a hexagonal closest-packed grid pattern, but is not limited thereto. In another embodiment, the plurality of reflective structure openings 400 may be arranged in various patterns. For example, a rectangular plaid pattern. As shown in FIGS. 2 and 4, the reflective structure 40 is located on the contact electrode 30 and covers the inclined surface S of the semiconductor mesa M, and also covers a part of the first semiconductor layer 21 and a part of the second semiconductor layer 23. For example, the reflective structure 40 may cover a part of the upper surface 21t of the first semiconductor layer 21 and a part of the upper surface 23t of the second semiconductor layer 23.

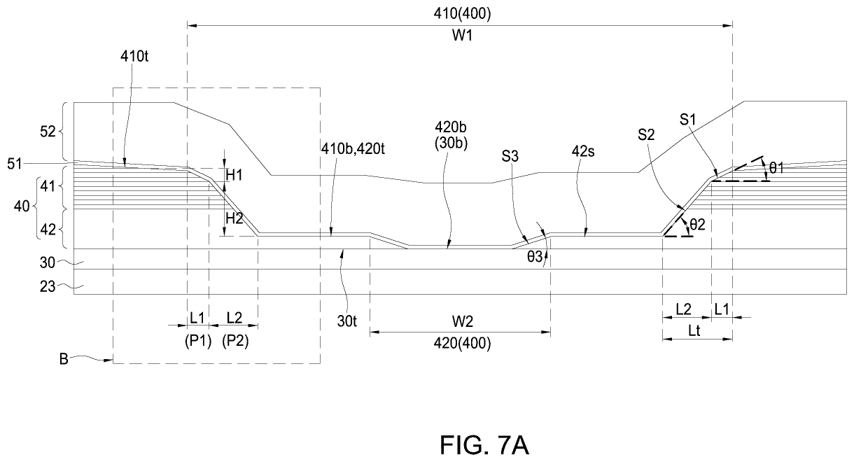

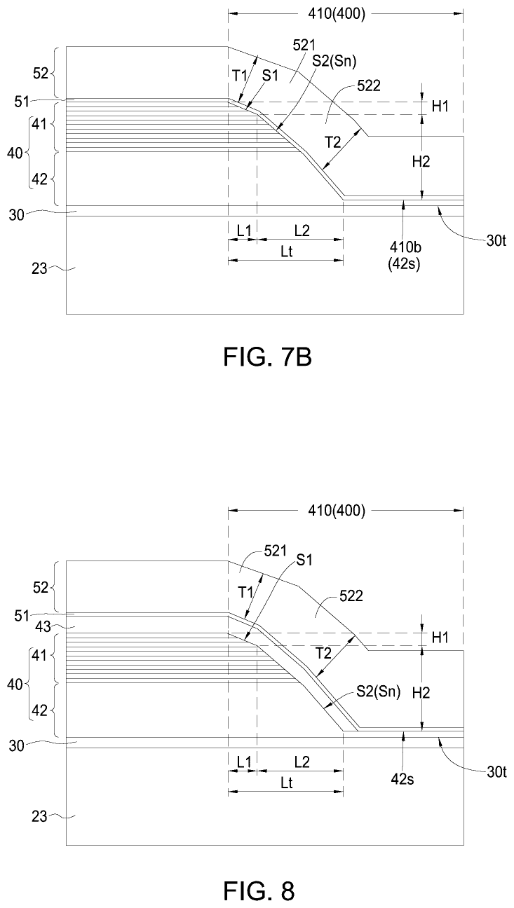

FIG. 7A is a side view of the reflective structure opening 400 disclosed in one embodiment of the present application. FIG. 7B is a partial enlarged view of region B defined by the dash line of FIG. 7A. In one embodiment, the reflective structure 40 comprises an insulating reflective mirror 41 and an insulating layer 42 which is located between the contact electrode 30 and the insulating reflective mirror 41. The reflective structure opening 400 comprises a first reflective structure opening 410 and a second reflective structure opening 420.

As shown from the side view of FIG. 7A, the reflective structure 40 comprises a plurality of side surfaces at the reflective structure opening 400 to define the outline of the reflective structure opening 400. In other words, the reflective structure opening 400 comprises a first side surface S1, a second side surface S2 and a third side surface S3, wherein the first reflective structure opening 410 is defined by the first side surface S1 and the second side surface S2, and the second reflective structure opening 420 is defined by the third side surface S3.

In order to increase the effective reflection area of the insulating reflective mirror 41 and enable the metal reflective layer 52 to evenly cover the first side surface S1 and the second side surface S2 of the reflective structure opening 400, in one embodiment, the first reflective structure opening 410 comprises a first opening width W1 larger than a second opening width W2 that the second reflective structure opening 420 comprises. In a side view of the light-emitting device 1, the first opening width W1 is between 9 μm and 15 μm, and the second opening width W2 is between 3 μm and 9 μm. In the side view of the light-emitting device 1, the first side surface S1 comprises a first acute angle θ1, the second side surface S2 comprises a second acute angle θ2, and the first acute angle θ1 is smaller than the second acute angle θ2. In one embodiment, the first acute angle θ1 is between 5 degrees and 35 degrees or between 10 degrees and 30 degrees. In one embodiment, the second acute angle θ2 is between 40 degrees and 70 degrees or between 30 degrees and 60 degrees. The third side surface S3 is connected to the contact electrode 30 and comprises a third acute angle θ3 in a range between 10 degrees and 30 degrees.

In a side view of the light-emitting device 1, a first portion P1 of a projection of the first side surface S1 of the reflective structure opening 400 to the upper surface 30t of the contact electrode 30 comprises a first length L1, a second portion P2 of a projection of the second side surface S2 of the reflective structure opening 400 to the upper surface 30t of the contact electrode 30 comprises a second length L2, and the first length L1 is smaller than the second length L2.

In one embodiment, the first length L1 and the second length L2 satisfy the equation

$$L 1 < \frac{1}{2} L 2.$$

When the opening width of the reflective structure opening 400 is fixed, the longer the first length L1 is, the smaller the effective reflection area of the reflective structure 40 is. It indirectly reduces the light extraction efficiency of the area adjacent to the reflective structure opening 400. In this embodiment, by adjusting the first length L1 and the second length L2, it can prevent the metal reflective layer 52 covering first side surface S1 and the second side surface S2 from cracking, and the reliability of the light-emitting device 1 can be improved.

In one embodiment, the total length Lt of the first length L1 and the second length L2 is between 0.5 μm and 2.5 μm. The longer the total length Lt is, the smaller the effective reflection area of the reflective structure 40 is. It indirectly reduces the light extraction efficiency of the area adjacent to the reflective structure opening 400.

In a side view of the light-emitting device 1, the first side surface S1 of the reflective structure opening 400 comprises a first height H1, the second side surface S2 of the reflective structure opening 400 comprises a second height H2, and the first height H1 is less than the second height H2.

In one embodiment, the first height H1 and the second height H2 satisfy the equation

$$H 1 < \frac{1}{2} H 2.$$

In a top view of the light-emitting device 1, the insulating layer 42 comprises an insulating layer upper surface 42s surrounding the second reflective structure opening 420, and the first reflective structure opening 410 and the second reflective structure opening 420 form concentric circles. In a side view of the light-emitting device 1, the insulating layer upper surface 42s is exposed in the first reflective structure opening 410, and the second side surface S2 of the reflective structure opening 400 is connected to the insulating layer upper surface 42s of the insulating layer 42. The first reflective structure opening 410 further comprises a first top portion 410t and a first bottom portion 410b, and the first bottom portion 410b and the insulating layer upper surface 42s are on the same horizontal plane. The second reflective structure opening 420 further comprises a second top portion 420t and a second bottom portion 420b. The second top portion 420t and the insulating layer upper surface 42s are on the same horizontal plane, and the second bottom portion 420b and the upper surface 30t of the contact electrode 30 are on the same horizontal plane.

In another embodiment (not shown), there is no insulating layer upper surface 42s in the first reflective structure opening 410, that is, the first side surface S1, the second side surface S2 and the third side surface S3 of the reflective structure opening 400 are located on the same inclined plane, arc surface or curved surface, and the third side surface S3 is directly connected to the upper surface 30t of the contact electrode 30.

In one embodiment, as shown in FIG. 7B, the first side surface S1 is composed of one part of the side surface of the insulating reflective mirror 41, the second side surface S2 is composed of another part of the side surface of the insulating reflective mirror 41 and one part of the side surface of the insulating layer 42, and the third side surface S3 is composed of another part of the side surface of the insulating layer 42. The second side surface S2 comprises a plurality of sub-side surfaces Sn having multiple slopes, and the plurality of sub-side surfaces Sn has multiple different slopes. In one embodiment, the multiple slopes of the plurality of sub-side surfaces Sn gradually change continuously or discontinuously. For example, the multiple slopes of the plurality of sub-side surfaces Sn gradually increase in a direction from the first top portion 410t toward the first bottom portion 410b. In one embodiment, the plurality of sub-side surfaces Sn with gradually increasing slopes can form an arc-shaped surface. In this embodiment, the second side surface S2 comprising a plurality of sub-side surfaces Sn is connected to the insulating layer upper surface 42s. In another embodiment (not shown), the second side surface S2 comprising a plurality of sub-side surfaces Sn is connected to the third side surface S3.

As shown in FIGS. 7A and 7B, the metal reflective layer 52 covers the connection layer 51, fills into the first reflective structure opening 410 and the second reflective structure opening 420, and is electrically connected to the contact electrode 30 through the connection layer 51. In the side view of the light-emitting device 1, the metal reflective layer 52 comprises a first metal portion 521 covering the first side surface S1 and a second metal portion 522 covering the second side surface S2. In one embodiment, the difference between a first thickness T1 of the first metal portion 521 and a second thickness T2 of the second metal portion 522 is less than 10% the first thickness T1 or the second thickness T2. In another embodiment, the second thickness T2 of the second metal portion 522 is less than or equal to 50% of the first thickness T1 of the first metal portion 521. In another embodiment, the second thickness T2 of the second metal portion 522 is more than or equal to 50% of the first thickness T1 of the first metal portion 521.

FIG. 8 is a partial side view of the first reflective structure opening 410 disclosed in another embodiment of the present application. In this embodiment, the light-emitting device 1 further comprises a dielectric layer 43 covering the first side surface S1 and the second side surface S2 of the reflective structure opening 400 and connected to the insulating layer upper surface 42s. The dielectric layer 43 can be made of a transparent insulating material and comprises one of the following materials: SiO₂, SiN, TiO₂, HfO, Al₂O₃, and MgF₂. In one embodiment, the insulating layer 42 and the dielectric layer 43 can comprise the same or different materials. For example, when the insulating reflective mirror 41 is made of DBR comprising SiO₂/TiO₂ or SiO₂/Nb₂O₅, the insulating layer 42 and the dielectric layer 43 can comprise SiO₂. As shown in FIG. 8, a portion where a plurality of first sub-layers and/or a plurality of second sub-layers of the insulating reflective mirror 41 connected to the dielectric layer 43 comprises a wedge shape. The plurality of wedge shapes of the plurality of first sub-layers and/or the plurality of second sub-layers has multiple different slopes, and the multiple slopes of the plurality of wedge shapes gradually increase in a direction from the first top portion 410t to the first bottom portion 410b to increase the effective reflection area of the insulating reflective mirror 41 and enable the metal reflective layer 52 to evenly cover the first side surface S1 and the second side surface S2 of the reflective structure opening 400.

As shown in FIGS. 2 and 4, the metal reflective layer 52 fills into the reflective structure opening 400 of the reflective structure 40 through the connection layer 51, wherein the connection layer 51 can improve the adhesion between the reflective structure 40 and the metal reflective layer 52. In a side view of the light-emitting device 1, in one embodiment, the metal reflective layer 52 can be disposed on the connection layer 51 and conform to the connection layer 51. For example, the metal reflective layer 52 and the connection layer 51 can completely overlap or partially overlap with each other.

In one embodiment, referring to FIGS. 1, 2, 3 and 4, the insulating reflective mirror 41 can be composed of a material with a refractive index lower than that of the second semiconductor layer 23. The material of the insulating reflective mirror 41 comprises SiO₂, SiN, SiOₓN_{y}, TiO₂, Si₃N₄, Al₂O₃, TiN, AlN, ZrO₂, TiAlN, TiSiN, HfO, TaO₂, Nb₂O₅, or MgF₂. In one embodiment, the insulating reflective mirror 41 has a multi-layer film structure in which insulating sub-layers with different refractive indexes are alternately stacked, such as a distributed Bragg reflector (DBR). A distributed Bragg reflector (DBR) structure is formed by alternately stacking a plurality of first sub-layers each having a first refractive index and a plurality of second sub-layers each having a second refractive index, and the first refractive index is less than the second refractive index. For example, SiO₂/TiO₂ or SiO₂/Nb₂O₅ can be stacked.

In one embodiment, the metal reflective layer 52 comprises silver (Ag), chromium (Cr), nickel (Ni), titanium (Ti), aluminum (Al), rhodium (Rh), ruthenium (Ru) or a combination of aforementioned materials.

In one embodiment, the light-emitting device 1 further comprises a barrier layer (not shown) disposed on the metal reflective layer 52. The barrier layer has a multi-layer structure, for example, a multi-layer structure with Ti and Ni alternately stacked.

In one embodiment, the insulating layer 42 of the reflective structure 40 taken as an insulating film and having a single-layer structure comprises oxide or nitride, for example, silicon oxide, silicon nitride, metal oxide or metal nitride while the metal can be selected from titanium (Ti), zirconium (Zr), niobium (Nb), tantalum (Ta), or aluminum (Al). In another embodiment, the insulating layer 42 may also be a multi-layer structure, such as a multi-layer structure composed of SiO₂ and Al₂O₃.

The bottommost layer or the topmost layer of the insulating reflective mirror 41 can use silicon oxide, silicon nitride, metal oxide or metal nitride while the metal can be selected from titanium (Ti), zirconium (Zr), niobium (Nb), tantalum (Ta), or aluminum (Al). In one embodiment, the bottommost layer and the topmost layer of the insulating reflective mirror 41 comprise different materials and/or different thicknesses and/or different formation processes from that of the intermediate layer.

In one embodiment, the insulating layer 42 can comprise the same material as at least a part of material of the plurality of first sub-layers of the insulating reflective mirror 41. For example, when the insulating reflective mirror 41 is made of DBR comprising SiO₂/TiO₂ or SiO₂/Nb₂O₅, the plurality of first sub-layers and the insulating layer 42 may be made of SiO₂. Although the insulating layer 42 is made of the same material as at least a part of material of the insulating reflective mirror 41, it is not required to have such a high film quality as the insulating film of DBR. Therefore, the insulating reflective mirror 41 and the insulating layer 42 can be made by different processes. The interface between the insulating layer 42 and the insulating reflective mirror 41 can thus be differentiated visually (e.g. SEM photos or TEM photos). In one embodiment, the total thickness of the plurality of first sub-layers of the insulating reflective mirror 41 is less than the total thickness of the insulating layer 42. The dielectric layer 43 as shown in FIG. 8 has a thickness greater than each thickness of the plurality of first sub-layers to cover the side surface of the insulating reflective mirror 41 completely.

FIG. 3 is a top view of the reflective structure opening 400 and the second recessed region E2 of region A defined by the dash line of FIG. 1. FIG. 4 is a cross-sectional view along line X-X′ of FIG. 3.

As shown in FIG. 3, a plurality of reflective structure openings 400 is arranged in an annular shape along the second boundary B2 between the second recessed region E2 and the semiconductor mesa M. The plurality of reflective structure openings 400 is evenly spaced apart from each other by a first shortest distance D1 so that the current injected into the light-emitting device 1 can be evenly distributed. In one embodiment, the first shortest distance D1 can be smaller than a minimum width W that the second recessed region E2 comprises. In one embodiment, the reflective structure opening 400 and the second boundary B2 are spaced apart by a second shortest distance D2, wherein the first shortest distance D1 can be greater than the second shortest distance D2.

As shown in FIGS. 2 and 4, the reflective structure 40 comprises a contact structure opening 411 located on the first recessed region E1 and the second recessed region E2. The second insulating layer 60 can expose the sidewalls of the contact structure opening 411, thus an opening width 601w that the first opening 601 of the second insulating layer 60 comprises is substantially the same as the width 411w of the contact structure opening 411. In another embodiment, the second insulating layer 60 can cover the sidewalls of the contact structure opening 411 (not shown), so that an opening width 601w that the first opening 601 of the second insulating layer 60 comprises is smaller than the width 411w of the contact structure opening 411. In another embodiment, there is a distance Smax between one side wall 601s of the first opening 601 of the second insulating layer 60 and the inclined surface S of the semiconductor mesa M, which is greater than 10 μm and less than 30 μm, thus the second insulating layer 60 can comprise a thickness which is thick enough to protect the reflective structure 40. The first extension electrode 71 is connected to the first semiconductor layer 21 exposed in the first recessed region E1 and the second recessed region E2 via the first opening 601 of the second insulating layer 60.

As shown in FIG. 4, the connection layer 51 is disposed on the reflective structure 40 and contacts the contact electrode 30 through the reflective structure opening 400. The contact electrode 30 and the connection layer 51 can comprise the same or different materials, but the connection layer 51 comprises a thickness smaller than that of the contact electrode 30. In one embodiment of the present application, the contact electrode 30 and the connection layer 51 comprise indium tin oxide (ITO). In one embodiment of the present application, the contact electrode 30 and the connection layer 51 comprise different materials. For example, the contact electrode 30 comprises indium tin oxide (ITO) and the connection layer 51 comprises aluminum oxide (Al₂O₃). In one embodiment, the thickness of the contact electrode 30 is in a range between 100 Å and 200 Å. The thickness of the connection layer 51 is in a range between 10 Å and 90 Å. The contact electrode 30 can comprise indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1). The connection layer 51 can comprise titanium oxide (TiOₓ), titanium nitride (TiNₓ), aluminum oxide (Al₂O₃), indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1).

As shown in FIG. 2, the second insulating layer 60 continuously covers all exposed surfaces of the metal reflective layer 52 and the connection layer 51 to protect the metal reflective layer 52, such as the upper surfaces and side surfaces of the metal reflective layer 52 and those of the connection layer 51. The metal reflective layer 52 and the connection layer 51 may be encapsulated between the second insulating layer 60 and the reflective structure 40. Forming the second insulating layer 60 can prevent the reflectivity of the metal reflective layer 52 from degradation caused by subsequent processes and suppress the migration of metal elements that the metal reflective layer 52 comprises. The second insulating layer 60 may be made of a transparent insulating material comprising SiO₂, SiN, TiO₂, HfO, or MgF₂.

The reflective structure 40, the connection layer 51 and the metal reflective layer 52 may be configured as an Omni-Directional reflector (ODR). The Omni-Directional reflector can increase the reflectivity of light emitted from the active layer 22, thereby improving the light extraction efficiency of the light-emitting device 1.

As shown in FIGS. 2 and 4, when the second insulating layer 60 is made of a transparent insulating material, the second insulating layer 60 comprises a first opening 601 and a second opening 602 of the second insulating layer 60. The first opening 601 of the second insulating layer 60 can be disposed on the first recessed region E1 and the second recessed region E2. The first opening 601 of the second insulating layer 60 is disposed corresponding to the contact structure opening 411 of the reflective structure 40 to expose the first semiconductor layer 21 in the first contact region CT1 and the first contact subregion CT1′. The second opening 602 of the second insulating layer 60 is located on the metal reflective layer 52 in the second contact region CT2.

In one embodiment, as shown in FIG. 1, the second opening 602 of the second insulating layer 60 and the plurality of reflective structure openings 400 are disposed in a staggered manner, that is, the second opening 602 of the second insulating layer 60 is not aligned with the plurality of reflective structure openings 400.

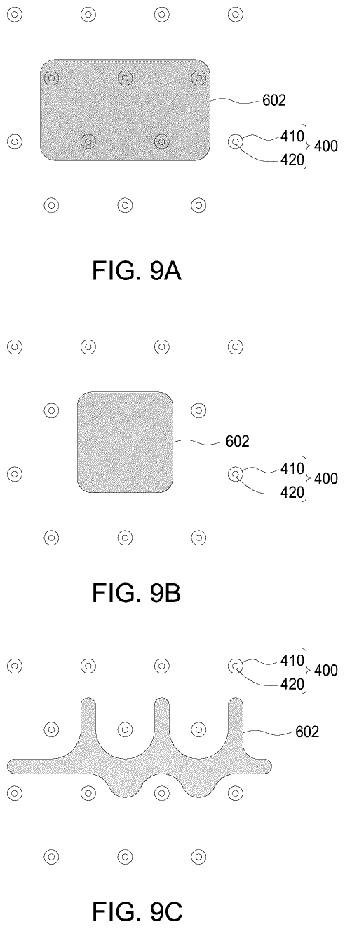

In order to make the plurality of reflective structure openings 400 arranged evenly spaced, the second opening 602 of the second insulating layer 60 comprises an irregular shape, and the plurality of reflective structure openings 400 are surrounded by the irregular shape of the second opening 602. In another embodiment, as shown in FIG. 9A, the second opening 602 of the second insulating layer 60 forms a rectangle, and the plurality of reflective structure openings 400 are surrounded by the rectangle of the second opening 602, wherein the second opening 602 of the second insulating layer 60 overlaps with the plurality of reflective structure openings 400. In another embodiment, as shown in FIG. 9B, the second opening 602 of the second insulating layer 60 comprises a rectangle, and the plurality of reflective structure openings 400 is located in an area outside the rectangle, wherein the second opening 602 of the second insulating layer 60 does not overlap with the plurality of reflective structure openings 400. In another embodiment, the rectangles in FIGS. 9A and 9B can be altered as circles, triangles, regular polygons, or irregular polygons.

In one embodiment, as shown in FIG. 1, the second opening 602 of the second insulating layer 60 comprises a network opening with a closed curved outer contour, and the plurality of reflective structure openings 400 comprises a first portion 4001 located inside the closed curved outer contour and a second portion 4002 located outside the closed curved outer contour, wherein the first portion 4001 and the second portion 4002 are arranged on the semiconductor mesa M in a hexagonal grid pattern. In another embodiment, as shown in FIG. 9C, the second opening 602 of the second insulating layer 60 comprises a closed curved outer contour, and a plurality of reflective structure openings 400 is located outside the closed curved outer contour and arranged on the semiconductor mesa M in a hexagonal grid pattern.

As shown in FIGS. 2 and 4, the first extension electrode 71 can be disposed on the second insulating layer 60 and extend to the first semiconductor layer 21 in the first contact region CT1 and the first contact subregion CT1′ to contact and be electrically connected to the first semiconductor layer 21 through the first opening 601 of the second insulating layer 60. In one embodiment, in order to improve the contact resistance characteristics between the first extension electrode 71 and the first semiconductor layer 21, a conductive contact layer (not shown) can be disposed between the first extension electrode 71 and the first semiconductor layer 21. The conductive contact layer can comprise indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum-doped zinc oxide (AZO), gallium-doped zinc oxide (GZO), zinc-magnesium oxide (Zn₍₁₋ₓ₎MgₓO, 0≤x≤1) and other conductive metal oxides. In one embodiment, a metal contact layer (not shown) can be disposed on the upper surface 20b of the first recessed region E1 and/or the upper surface 20b′ of the second recessed region E2. A part of the upper surface of the metal contact layer can be the first contact region CT1 and/or the first contact subregion CT1′

The second extension electrode 72 can be disposed on the second insulating layer 60 and extend to contact the metal reflective layer 52 through the second opening 602 of the second insulating layer 60, thereby being electrically connected to the second semiconductor layer 23.

The first extension electrode 71 and the second extension electrode 72 can be disposed on the second insulating layer 60, made of the same material, and spaced apart from each other. For example, the first extension electrode 71 and the second extension electrode 72 may be made of a material comprising aluminum (Al), gold (Au), tungsten (W), platinum (Pt), iridium (Ir), silver (Ag), copper (Cu), nickel (Ni), titanium (Ti), chromium (Cr) and alloys of the above materials.

As shown in FIG. 2, the protection layer 80 comprises a first opening 801 of the protection layer 80 located on the first extension electrode 71 and a second opening 802 of the protection layer 80 located on the second extension electrode 72. The first opening 801 of the protection layer 80 can expose the third contact region CT3 of the first extension electrode 71, and the second opening 802 of the protection layer 80 can expose the fourth contact region CT4 of the second extension electrode 72.

The first electrode pad 91 can be disposed on the third contact region CT3 through the first opening 801 of the protection layer 80, and the second electrode pad 92 can be disposed on the fourth contact region CT4 through the second opening 802 of the protection layer 80. A first soldering pad (not shown) can be disposed on the first electrode pad 91, and a second soldering pad (not shown) can be disposed on the second electrode pad 92. The first soldering pad and the second soldering pad can be made of a conductive material (e.g. Sn or AuSn). As shown in FIG. 1, in a top view, the first electrode pad 91 can be adjacent to the first side 11, and the second electrode pad 92 can be adjacent to the second side 12.

The first extension electrode 71, the second extension electrode 72, the first electrode pad 91, and the second electrode pad 92 comprise metal materials, such as chromium (Cr), titanium (Ti), tungsten (W), gold (Au), aluminum (Al), indium (In), tin (Sn), nickel (Ni), platinum (Pt), silver (Ag) and other metals or alloys of the above materials. The first extension electrode 71, the second extension electrode 72, the first electrode pad 91, and the second electrode pad 92 can be composed of a single layer or multiple layers. For example, the first extension electrode 71, the second extension electrode 72, the first electrode pad 91, or the second electrode pad 92 can comprise a Ti/Au layer, a Ti/Pt/Au layer, a Cr/Au layer, a Cr/Pt/Au layer, a Ni/Au layer, a Ni/Pt/Au layer, a Cr/Al/Cr/Ni/Au layer, or a Ag/NiTi/TiW/Pt layer. The first electrode pad 91 and the second electrode pad 92 can serve as current paths for external power supply into the first semiconductor layer 21 and the second semiconductor layer 23. The first extension electrode 71, the second extension electrode 72, the first electrode pad 91, and the second electrode pad 92 each comprises a thickness in a range between 0.5 μm and 5 μm.

The insulating layer 42, the second insulating layer 60 and the protection layer 80 are disposed on the semiconductor structure 20 and serve as a protection film and an anti-static interlayer insulating film for the light-emitting device 1. In one embodiment, as an insulating film, the insulating layer 42, the second insulating layer 60 and the protection layer 80 can be a single-layer structure comprising silicon oxide, silicon nitride, metal oxide or metal nitride. For example, the metal of metal oxide or metal nitride can be selected from titanium (Ti), zirconium (Zr), niobium (Nb), tantalum (Ta), or aluminum (Al). In one embodiment, the insulating layer 42, the second insulating layer 60 and the protection layer 80 comprise two or more materials with different refractive indexes that are alternately stacked to form a distributed Bragg reflector (DBR) structure to selectively reflect light of specific wavelengths. For example, a reflective structure with high reflectivity can be formed by stacking two or three insulating sub-layers with materials such as SiO₂, TiO₂, Nb₂O₅ or Al₂O₃. For example, when sub-layers such as SiO₂/TiO₂ or SiO₂/Nb₂O₅ are stacked to form a distributed Bragg reflector (DBR) structure, an optical thickness of each sub-layer of the distributed Bragg reflector structure is designed to be one or an integer multiple of a quarter of the wavelength of the light emitted from the active layer 22. The optical thickness of each sub-layer of the distributed Bragg reflector structure may have a deviation of ±30% based on one or an integer multiple of λ/4. Since the change in the optical thickness of each sub-layer of the distributed Bragg reflector structure can affect the reflectivity, the physical thickness of each sub-layer of the insulating layer 42, the second insulating layer 60 and the protection layer 80 which is obtained based on the optical thickness of the distributed Bragg reflector structure can be formed by using E-beam evaporation to stably control the thickness of each sub-layer of the insulating layer 42, the second insulating layer 60 and the protection layer 80.

In one embodiment of the present application, when the insulating reflective mirror 41 comprises a distributed Bragg reflector structure with stacked SiO₂/TiO₂ or SiO₂/Nb₂O₅, the insulating layer 42 has a thickness greater than a thickness of each sub-layer that the insulating reflective mirror 41 comprises. In one embodiment of the present application, the thickness of the insulating layer 42 ranges between 3000 Å and 7000 Å.

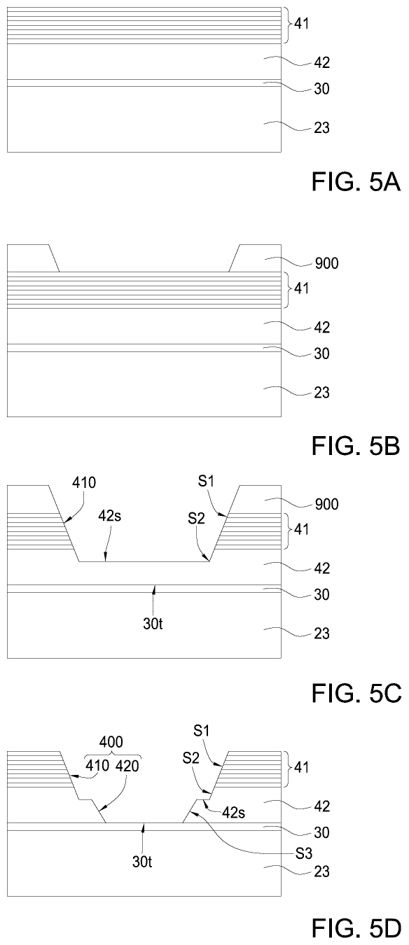

FIGS. 5A to 5D are cross-sectional views of a method for manufacturing the reflective structure opening 400 of the light-emitting device 1 disclosed in an embodiment of the present application.

As shown in FIG. 5A, a contact electrode 30 that can form ohmic contact with the second semiconductor layer 23 is first formed. Then, an insulating layer 42 is formed on the contact electrode 30, and an insulating reflective mirror 41 is formed on the insulating layer 42. Referring to FIGS. 2 and 4, when the insulating reflective mirror 41 covers the inclined surface S of the semiconductor mesa M, the angle of the inclined surface S can affect the coating quality of the insulating reflective mirror 41. For example, when the insulating reflective mirror 41 covers the semiconductor mesa M, it tends to form a fracture surface (not shown) at the junction between the inclined surface S of the semiconductor mesa M and the upper surface 21t of the first semiconductor layer 21 or at the junction between the inclined surface S of the semiconductor mesa M and the upper surface 23t of the second semiconductor layer 23. Thus, water vapor form outside tends to invade the semiconductor structure 20 through the fracture surface to reduce the reliability of the light-emitting device 1. In order to solve the problem caused from the above-mentioned fracture, in this embodiment, the insulating layer 42 is formed before forming the insulating reflective mirror 41. The insulating layer 42 has a denser film quality than the insulating reflective mirror 41 and/or has a more uniform film thickness. When the insulating reflective mirror 41 comprises a plurality of sub-layers, the film thickness of the insulating layer 42 is thicker than the thickness of the plurality of sub-layers of the insulating reflective mirror 41. The insulating layer 42 can be formed by the same or different method for manufacturing the insulating reflective mirror 41. In one embodiment, chemical vapor deposition (CVD) or plasma enhanced chemical vapor deposition (PECVD) may be used to form the insulating layer 42 with better coverage and coating characteristics. In one embodiment, the high step coverage characteristics of atomic layer deposition (ALD) can be utilized to form the insulating reflective mirror 41 or the insulating layer 42 with uniform thickness. When the insulating reflective mirror 41 comprises a distributed Bragg reflector (DBR) structure, the thickness of each sub-layer of the distributed Bragg reflector (DBR) structure can affect the reflectivity of the insulating reflective mirror 41. In this embodiment, the insulating reflective mirror 41 can be formed by E-beam evaporation to stably control the thickness of each sub-layer of the distributed Bragg reflector (DBR) structure.

As shown in FIG. 5B, a mask layer 900 is formed on the insulating reflective mirror 41 by steps of spin coating, exposure, and development, for example.

As shown in FIG. 5C, part of the insulating reflective mirror 41 where not covered by the mask layer 900 is removed by a first etching, wherein the method of removing the insulating reflective mirror 41 comprises dry etching or wet etching. In one embodiment, it can be performed to use the mask layer 900 having openings of a first diameter to etch the insulating reflective mirror 41 by dry etching to form the first side surface S1 and the second side surface S2. The insulating layer 42 can serve as a protection layer or a stop layer for dry etching to prevent the contact electrode 30 and the second semiconductor layer 23 of the light-emitting device 1 from damage caused by the plasma ion source during the dry etching process.

To prevent the residue from the insulating reflective mirror 41, the insulating layer 42 may be over-etched by 5% to 30% during the first etching to form the first reflective structure opening 410 and expose the insulating layer upper surface 42s to ensure that there is no residue of the insulating reflective mirror 41. In another embodiment, during the process of forming the first reflective structure opening 410, the entire depth of the insulating layer 42 can be etched by the first etching to make the upper surface 30t of the contact electrode 30 exposed, so that a side wall of the second reflective structure openings 420 and a side wall of the first reflective structure opening 410 are located on the inclined surface.

As shown in FIG. 5D, the insulating layer 42 is removed by a second etching until the contact electrode 30 is exposed. In one embodiment, it can be performed by using a mask layer (not shown) having openings of a second diameter to remove the insulating layer 42 to form the second reflective structure opening 420 having the third side surface S3. The method of removing the insulating layer 42 in the second etching may be the same as or different from the method of removing the insulating reflective mirror 41 in the first etching. In this embodiment, the first etching is performed by dry etching, and the second etching is performed by wet etching which is different from the first etching. In one embodiment, the second diameter of the mask layer during the second etching process can be less than or equal to the first diameter of the mask layer during the first etching process. The mask layer 900 can be composed of a material that is easily removable, such as polyimide or photoresist. When the material of the mask layer 900 is polyimide or photoresist, it can be removed by plasma etching. In one embodiment, the second etching can be performed by adjusting the etching gas or liquid to reduce the damage to the contact electrode 30 during the second etching to meet the requirement of less physical damage. In another embodiment, the damage to the contact electrode 30 caused by the second etching can be reduced by reducing the etching time.

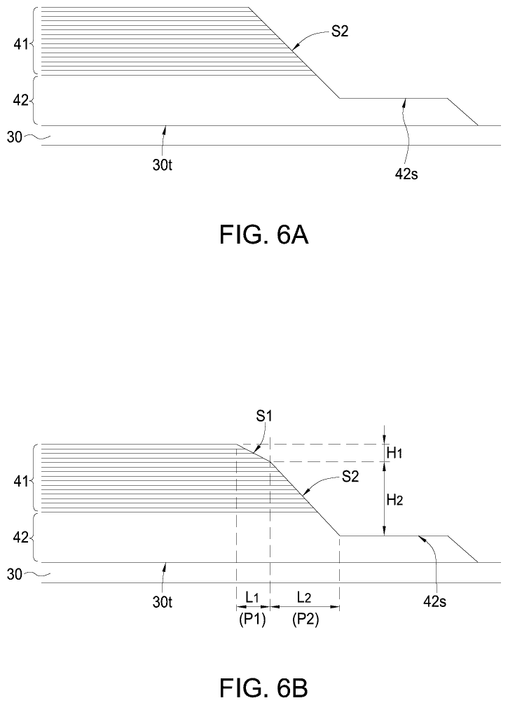

FIGS. 6A to 6B are cross-sectional views of a method for manufacturing the first reflective structure opening 410 of FIG. 5A disclosed in an embodiment of the present application. In the first etching process for forming the first reflective structure opening 410, by adjusting the ratio of the lateral etching rate (the direction parallel to the upper surface 10s of the substrate 10 shown in FIG. 1) to the vertical etching rate (the direction perpendicular to the upper surface 10s of the substrate 10 shown in FIG. 1) during the multi-stage etching, the first side surface S1 and the second side surface S2 can have different slopes. Specifically, as shown in FIG. 6A, the insulating layer 42 is first over-etched by 5% to 30% to form the second side surface S2 and expose the insulating layer upper surface 42s during the first stage of the first etching. As shown in FIG. 6B, the first side surface S1 is formed during the second stage of the first etching subsequent to the first stage of the first etching.

In one embodiment, a first portion P1 of a projection of the first side surface S1 to the upper surface 30t of the contact electrode 30 comprises a first length L1, a second portion P2 of a projection of the second side surface S2 to the upper surface 30t of the contact electrode 30 comprises a second length L2, and the first length L1 is smaller than the second length L2.

In one embodiment, the first length L1 and the second length L2 satisfy the equation

$$L 1 < \frac{1}{2} L 2.$$

In one embodiment, the first side surface S1 comprises a first height H1, the second side surface S2 comprises a second height H2, and the first height H1 is less than the second height H2.

In one embodiment, the first height H1 and the second height H2 satisfy the equation

$$H 1 < \frac{1}{2} H 2.$$

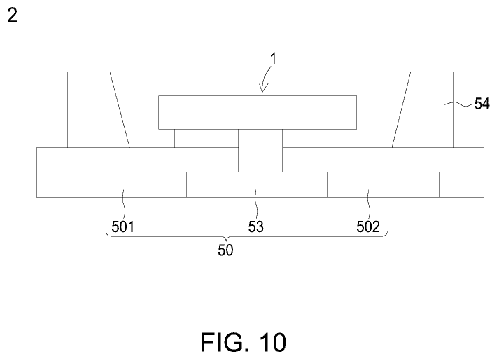

FIG. 10 is a schematic view of a light-emitting apparatus 2 disclosed in an embodiment of the present application. The light-emitting device 1 can be selected from the foregoing embodiments, and is mounted on the first spacer 501 and the second spacer 502 of the package substrate 50 in the form of flip-chip. The first spacer 501 and the second spacer 502 are electrically insulated from each other by an insulating portion 53 comprising an insulating material. The main light-extraction surface of the flip-chip is one side of the growth substrates opposite to the surface where the electrode pad formed, such as the light-emitting surface 10t of the substrate 10 of the light-emitting device 1 is the main light-extraction surface. A reflective structure 54 can be provided around the light-emitting device 1 to increase the light extraction efficiency of the light-emitting apparatus 2.

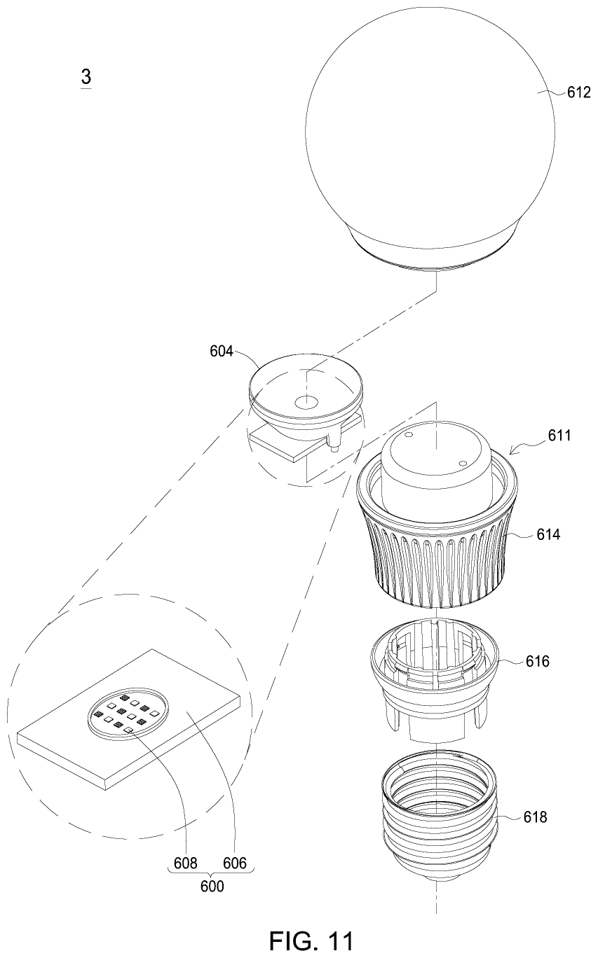

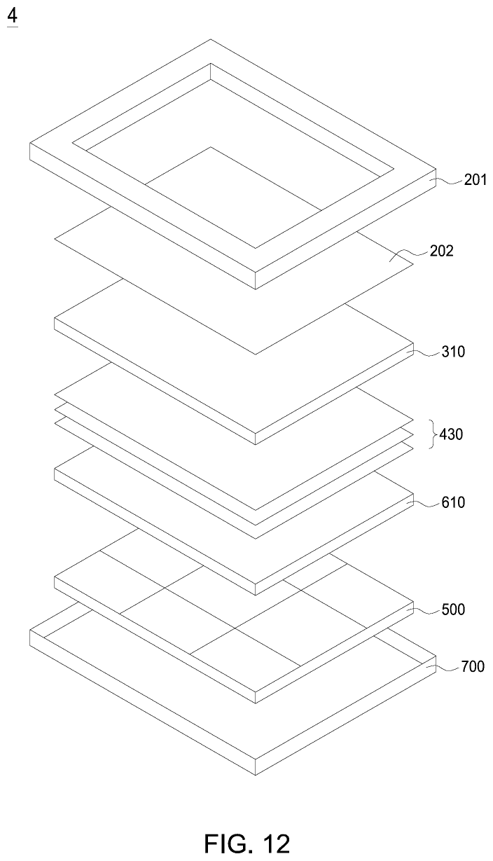

FIG. 11 is a schematic view of a light-emitting apparatus 3 disclosed in an embodiment of the present application. The light-emitting apparatus 3 is a light bulb comprising an envelope 612, a lens 604, a light-emitting module 600, a base 611, a heat sink 614, a connector 616 and an electrical connecting device 618. The light-emitting module 600 comprises a submount 606 and a plurality of light-emitting devices 608 on the submount 606, wherein the plurality of light-emitting devices 608 can be the light-emitting device 1 or the light-emitting apparatus 2 described in above embodiments.

FIG. 12 is a schematic view of the backlight module 4 according to an embodiment of the present application. The backlight module 4 comprises a first frame 201, a liquid crystal display panel 202, a brightness enhancement film 310, an optical module 430, a light-emitting module assembly 500, and a second frame 700. The light-emitting module assembly 500 comprises a plurality of the light-emitting devices 1 or the light-emitting apparatuses 2 described in above embodiments, which are arranged in the light-emitting module assembly 500 in an edge type or direct type light emission manner. In one embodiment, the backlight module 4 further comprises a wavelength conversion structure 610 disposed on the light-emitting module assembly 500.

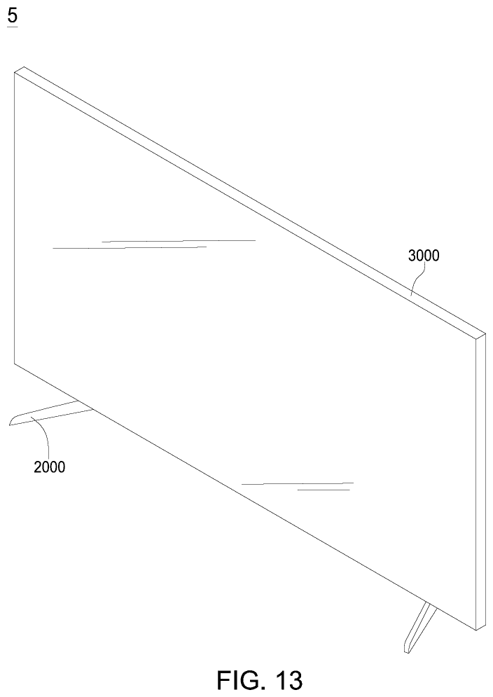

FIG. 13 is a schematic view of a display 5 according to an embodiment of the present application. The display 5 comprises an LED light-emitting panel 3000 and a current source (not shown). The bracket 2000 is used to support the LED light-emitting panel 3000. The LED light-emitting panel 3000 comprises any one of the light-emitting devices 1 or the light-emitting apparatuses 2 or the backlight modules 4 described in above embodiments. In one embodiment, the LED light-emitting panel 3000 comprises a plurality of pixel units. Each pixel unit comprises a plurality of the light-emitting devices 1 or light-emitting apparatuses 2 in the aforementioned embodiments to respectively emit different colors. For example, each pixel unit comprises three light-emitting devices 1 or light-emitting apparatuses 2 that respectively emit red light, green light, and blue light.

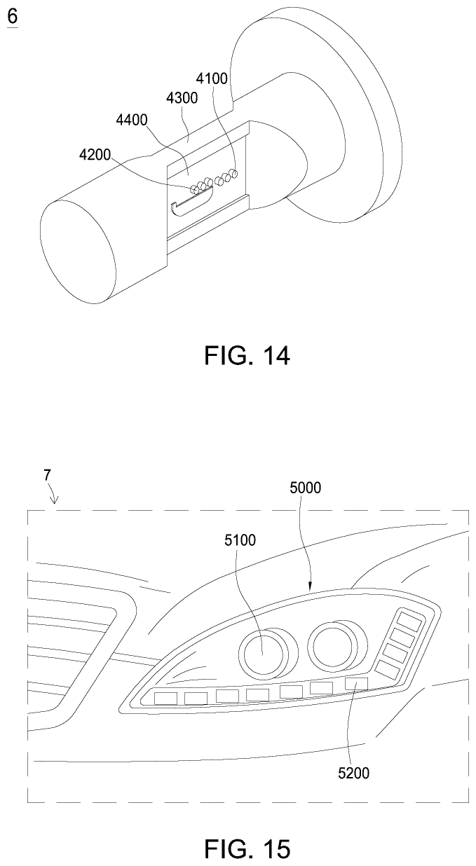

FIG. 14 is a schematic view of a light emitting apparatus 6 according to an embodiment of the present application. In one embodiment, the light-emitting apparatus 6 is an LED bulb for automobiles, which can be plugged and fixed into the mounting through hole on the rear housing of the automobile headlight assembly. The light-emitting apparatus 6 comprises a first LED chip 4100 for low beam lighting or a second LED chip 4200 for high beam lighting, a long columnar lamp post 4300, a driving power circuit board 4400, and heat dissipation fins for heat dissipation (not shown), a fan for heat dissipation (not shown), a fan cover for protecting the fan (not shown), a power cord for electrical connection with the vehicle battery (not shown), and a plug arranged at the end of the power cord (not shown). The first LED chip 4100 or the second LED chip 4200 in the light-emitting apparatus 6 may comprise any one or more of the aforementioned light-emitting devices 1 or light-emitting apparatuses 2.

FIG. 15 is a schematic view of a light emitting apparatus 7 according to an embodiment of the present application. In one embodiment, the light-emitting apparatus 7 can be a vehicle lighting lamp 5000, which can be applied in daytime running lights, headlights, tail lights, or direction lights. The main lighting lamp 5100 may be a main light-emitting lamp in the vehicle lighting lamp 5000. For example, when the vehicle lighting lamp 5000 is taken as a headlight, the main lighting lamp 5100 may function as a headlight that can illuminate the front of the vehicle. The combination lighting lamp 5200 can have at least two functions. For example, when the vehicle lighting lamp is used as a headlight, the combination lighting lamp 5200 can perform the functions of a daytime running light (DRL) and a direction indicator lamp. The main lighting lamp 5100 or the combination lighting lamp 5200 may comprise any one or more of the aforementioned light-emitting devices 1 or light-emitting apparatuses 2.

The elements of some of the embodiments as described above can facilitate those with ordinary knowledge in the technical field to which this disclosure belongs to better understand the viewpoints of the embodiments of the present disclosure. Those with ordinary skill in the art to which this disclosure belongs should understand that they can design or modify other processes and structures based on the embodiments of the disclosure to achieve the same purposes and/or advantages as the embodiments introduced here. Those with ordinary knowledge in the technical field to which this disclosure belongs should also understand that such equivalent structures do not deviate from the spirit and scope of the disclosure, and they can do various changes, replacements and substitutions without departing from the spirit and scope of this disclosure. Therefore, the protection scope of the present disclosure shall be subject to the scope of the appended claims. In addition, although the disclosure has been disclosed with several preferred embodiments as above, they are not intended to limit the disclosure.

Reference throughout the specification to features, advantages, or similar language does not imply that all features and advantages that can be realized with the present disclosure should or can be realized in any single embodiment of the present disclosure. In contrast, language referring to features and advantages is to be understood to mean that a particular feature, advantage, or characteristic described in connection with the embodiment is of at least an embodiment of the present disclosure. Thus, discussions of features and advantages, and similar language, throughout the specification may, but not necessarily, be representative of the same embodiments.

Furthermore, the described features, advantages, and characteristics of the present disclosure may be combined in any suitable manner in one or more embodiments. From the description herein, those skilled in the relevant art will appreciate that the present disclosure may be practiced without one or more of the specific features or advantages of a particular embodiment. In other instances, additional features and advantages may be identified in certain embodiments that may not be present in all embodiments of the present disclosure.

What is claimed is:

1. A light-emitting device, comprising:
a first semiconductor layer;
a semiconductor mesa, comprising an active layer and a second semiconductor layer and comprising an inclined surface connected to the first semiconductor layer;
a contact electrode covering the second semiconductor layer and comprising an upper surface;
a reflective structure comprising an insulating reflective mirror and an insulating layer located between the contact electrode and the insulating reflective mirror, wherein the reflective structure comprises a reflective structure opening and the reflective structure opening comprises a first side surface and a second side surface;
a connection layer covering the reflective structure and filling into the reflective structure opening; and
a metal reflective layer covering the connection layer and filling into the reflective structure opening;
wherein in a cross-sectional view of the light-emitting device, a first portion of a projection of the first side surface to the upper surface of the contact electrode comprises a first length L1, a second portion of a projection of the second side surface to the upper surface of the contact electrode comprises a second length L2, and the first length L1 is smaller than the second length L2.

2. The light-emitting device according to claim 1, wherein the reflective structure opening comprises a first reflective structure opening and a second reflective structure opening, the second reflective structure opening comprises a second opening width and the first reflective structure opening comprises a first opening width greater than or equal to the second opening width.

3. The light-emitting device according to claim 2, wherein in the cross-sectional view of the light-emitting device, the first opening width is in a range between 9 μm and 15 μm.

4. The light-emitting device according to claim 2, wherein in the cross-sectional view of the light-emitting device, the second opening width is in a range between 3 μm and 9 μm.

5. The light-emitting device according to claim 2, wherein from a top view of the light-emitting device, the first opening width is larger than the second opening width, the insulating layer comprises an insulating layer upper surface exposed in the first reflective structure opening and surrounding the second reflective structure opening.

6. The light-emitting device according to claim 5, wherein the second side surface is connected to the insulating layer upper surface.

7. The light-emitting device according to claim 2, wherein from a top view of the light-emitting device, the first reflective structure opening and the second reflective structure opening form concentric circles.

8. The light-emitting device according to claim 1, wherein the first side surface comprises a first acute angle, the second side surface comprises a second acute angle, and the first acute angle is smaller than the second acute angle.

9. The light-emitting device according to claim 8, wherein the first acute angle is in a range between 10 degrees and 30 degrees.

10. The light-emitting device according to claim 8, wherein the second acute angle is in a range between 30 degrees and 60 degrees.

11. The light-emitting device according to claim 2, wherein the reflective structure opening comprises a third side surface connected to the contact electrode.

12. The light-emitting device according to claim 11, wherein the third side surface comprises a third acute angle in a range between 10 degrees and 30 degrees.

13. The light-emitting device according to claim 1, wherein the first length L1 and the second length L2 satisfy an equation
$$L 1 < \frac{1}{2} L 2.$$

14. The light-emitting device according to claim 1, wherein a total length of the first length L1 and the second length L2 is in a range between 0.5 μm and 2.5 μm.

15. The light-emitting device according to claim 1, wherein the first side surface comprises a first height H1, the second side surface comprises a second height H2, and the first height H1 is smaller than the second height H2.

16. The light-emitting device according to claim 15, wherein the first height H1 and the second height H2 satisfy an equation
$$H 1 < \frac{1}{2} H 2.$$

17. The light-emitting device according to claim 1, wherein the insulating reflective mirror comprises a distributed Bragg reflector (DBR) covering the inclined surface of the semiconductor mesa, the distributed Bragg reflector is formed by alternately stacking a plurality of first sub-layers each having a first refractive index and a plurality of second sub-layers each having a second refractive index, the first refractive index is less than the second refractive index, and a total thickness of the plurality of first sub-layers is smaller than a total thickness of the insulating layer.

18. The light-emitting device according to claim 5, wherein the first reflective structure opening comprises a first top portion and a first bottom portion, and the first bottom portion is the insulating layer upper surface.

19. The light-emitting device according to claim 18, wherein the second side surface comprises a plurality of sub-side surfaces having multiple slopes, and the multiple slopes of the plurality of sub-side surfaces gradually increase in a direction from the first top portion to the first bottom portion.

20. The light-emitting device according to claim 5, wherein the second reflective structure opening comprises a second top portion and a second bottom portion, the second top portion and the insulating layer upper surface are on the same horizontal plane, and the second bottom portion is the upper surface of the contact electrode.
